(19) United States
(12) Patent Application Publication
(10) Pub. No.: US 2026/0280487 A1
(43) Pub. Date: Sep. 17, 2026

(54) PROCESSING DEVICE, PROCESSING METHOD, AND STORAGE MEDIUM

(71) Applicant: NEC Corporation, Tokyo (JP)

(72) Inventor: Tomohiro YAMAJI, Tokyo (JP)

(73) Assignee: NEC Corporation, Tokyo (JP)

(21) Appl. No.: 19/556,668

(22) Filed: Mar. 4, 2026

(30) Foreign Application Priority Data
Mar. 14, 2025 (JP) 2025-041551

(51) Int. Cl. H03D 7/16

(52) U.S. Cl. CPC H03D 7/165

(57) ABSTRACT

A processing device includes an oscillator to which a branch unit including an input unit and an output unit is connected, an input circuit for inputting a first signal wave for controlling an oscillation state of the oscillator to the oscillator via the input unit, a reading circuit for reading the oscillation state of the oscillator, which is connected to the output unit, and a mixer for mixing a second signal wave that is a wave having a phase opposite to a phase of a reflected wave of a first signal wave mixed in the output unit, with the first signal wave between the output unit and the reading circuit.

This application is based upon and claims the benefit of priority from Japanese patent application No. 2025-041551, filed on Mar. 14, 2025, the disclosure of which is incorporated herein in its entirety by reference.

### TECHNICAL FIELD

The present disclosure relates to a processing device, a processing method, and a program.

### BACKGROUND ART

The development of quantum computers has been carried out as one of the approaches to speeding up computer calculation. JP 2019-530336 A discloses a technique related to a quantum computing device as a related technique.

### SUMMARY

In a technical field of a quantum computer related to a quantum computing device as disclosed in JP 2019-530336 A, a technique capable of reducing an input wave reflected by an oscillator is required.

An object of each aspect of the present disclosure is to provide a processing device, a processing method, and a program that can solve the above problems.

According to an aspect of the present disclosure, a processing device includes input means for inputting a first signal wave for controlling an oscillation state of an oscillator to the oscillator to which a branch unit including an input unit and an output unit is connected, via the input unit, reading means for reading the oscillation state of the oscillator, which is connected to the output unit, and mixing means for mixing a second signal wave that is a wave having a phase opposite to a phase of a reflected wave of a first signal wave mixed in the output unit, with the first signal wave between the output unit and the reading means.

According to another aspect of the present disclosure, a processing method includes inputting a first signal wave for controlling an oscillation state of an oscillator to the oscillator to which a branch unit including an input unit and an output unit is connected, via the input unit, reading the oscillation state of the oscillator by reading means connected to the output unit, and mixing a second signal wave that is a wave having a phase opposite to a phase of a reflected wave of a first signal wave mixed in the output unit, with the first signal wave between the output unit and the reading means.

According to still another aspect of the present disclosure, a program causes a computer to execute inputting a first signal wave for controlling an oscillation state of an oscillator to the oscillator to which a branch unit including an input unit and an output unit is connected, via the input unit, reading the oscillation state of the oscillator by reading means connected to the output unit, and mixing a second signal wave that is a wave having a phase opposite to a phase of a reflected wave of a first signal wave mixed in the output unit, with the first signal wave between the output unit and the reading means.

According to each aspect of the present disclosure, it is possible to reduce an input wave that is reflected by an oscillator and is generated when the oscillator oscillates.

### BRIEF DESCRIPTION OF THE DRAWINGS

FIG. 1 is a diagram illustrating an example of a configuration of a processing system according to some example embodiments of the present disclosure;

FIG. 2 is a diagram illustrating an example of a configuration of a KPO according to some example embodiments of the present disclosure;

FIG. 3 is a diagram for describing processing performed by a pulse generation device and a pulse measurement device according to some example embodiments of the present disclosure;

FIG. 4 is a first diagram illustrating an image of a configuration of a processing system including a capacitor according to some example embodiments of the present disclosure;

FIG. 5 is a second diagram illustrating an image of a configuration of a processing system including a capacitor according to some example embodiments of the present disclosure;

FIG. 6 is a diagram illustrating an example of a processing flow of a processing system according to some example embodiments of the present disclosure;

FIG. 7 is a diagram illustrating an example of a configuration of a processing device according to some example embodiments of the present disclosure;

FIG. 8 is a diagram illustrating an example of a processing flow of the processing device according to some example embodiments of the present disclosure; and

FIG. 9 is a schematic block diagram illustrating a configuration of a computer according to at least one example embodiment.

### EXAMPLE EMBODIMENT

Hereinafter, example embodiments will be described in detail with reference to the drawings.

### EXAMPLE EMBODIMENT

A processing system 1 (an example of a processing device) according to an example embodiment of the present disclosure will be described with reference to the drawings. The processing system 1 is a system capable of reducing adverse effects due to mixing of control signals when reading an oscillation state of an oscillator.

### (Configuration of Processing System in Present Disclosure)

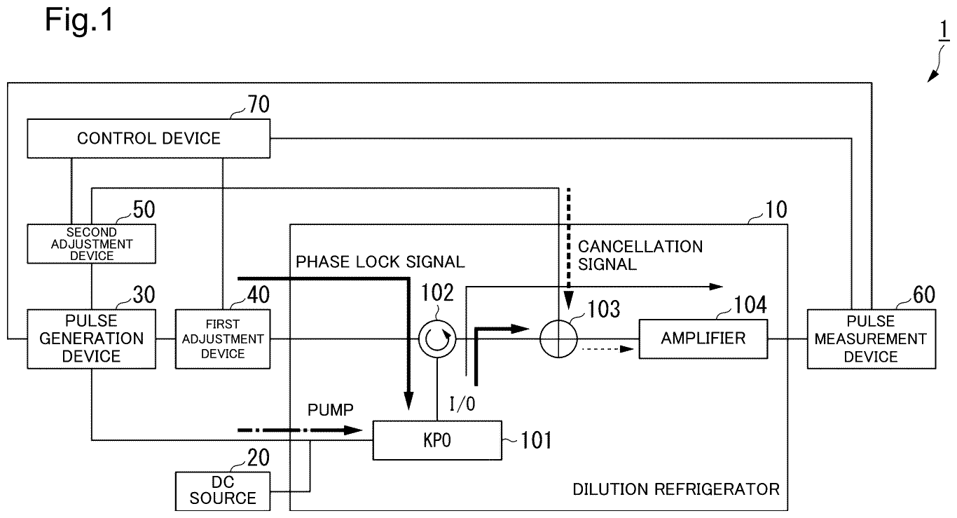

FIG. 1 is a diagram illustrating an example of a configuration of the processing system 1 according to some example embodiments of the present disclosure. As illustrated in FIG. 1, the processing system 1 according to an example embodiment of the present disclosure includes a dilution refrigerator 10, a direct current (DC) source 20, a pulse generation device 30, a first adjustment device 40, a second adjustment device 50, a pulse measurement device 60, and a control device 70.

As illustrated in FIG. 1, the dilution refrigerator 10 includes a Kerr parametric oscillator (KPO) 101, a branch unit 102, a combiner 103, and an amplifier 104.

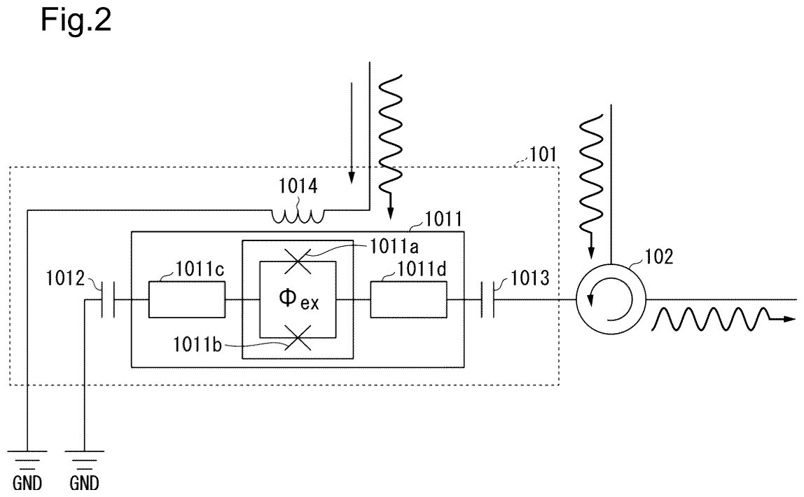

FIG. 2 is a diagram illustrating an example of a configuration of the KPO 101 according to some example embodiments of the present disclosure. As illustrated in FIG. 2, the KPO 101 includes a Josephson parametric oscillator (JPO) 1011 configured by a superconducting circuit, capacitors 1012 and 1013, and an inductor 1014.

As illustrated in FIG. 2, the JPO 1011 includes Josephson junctions 1011a and 1011b and resonators 1011c and 1011d. As illustrated in FIG. 2, the Josephson junctions 1011a and 1011b are connected in parallel. For example, the Josephson junctions 1011a and 1011b are a dc-SQUID (Superconducting QUantum Interference Device).

As illustrated in FIG. 2, the resonator 1011c is connected to one end of the Josephson junction 1011a. As illustrated in FIG. 2, the resonator 1011d is connected to the other end of the Josephson junction 1011a. That is, in the JPO 1011, the resonator 1011c, the Josephson junctions 1011a and 1011b connected in parallel, and the resonator 1011d are connected in series. The resonators 1011c and 1011d each have a length of about λ/4 and constitute a λ/2 resonator that resonates at about λ/2 of a signal with the SQUID. A is the wavelength of a signal. Oscillation occurs at about λ/2 of a signal by the resonators 1011c and 1011d and the dc-SQUID. That is, the resonators 1011c and 1011d and the dc-SQUID constitute a resonator that resonates at about λ/2 of a signal. The resonators 1011c and 1011d and the dc-SQUID operate as oscillators by causing resonance frequencies of the resonators to vary.

As illustrated in FIG. 2, one end of the capacitor 1012 is connected to one end of the JPO 1011 in series with the JPO 1011. As illustrated in FIG. 2, the other end of the capacitor 1012 is connected to a ground GND.

As illustrated in FIG. 2, one end of the capacitor 1013 is connected to the other end of the JPO 1011 in series with the JPO 1011. As illustrated in FIG. 2, the other end of the capacitor 1013 is connected to the branch unit 102.

As illustrated in FIG. 2, the inductor 1014 is provided in a pump line connected to the ground GND. The pump line is a signal line through which a pump wave in which a bias current (DC current) output from the DC source 20 and a signal output from the pulse generation device 30 are combined propagates. The inductor 1014 is inductively coupled to the Josephson junctions 1011a and 1011b (that is, the dc-SQUID) by mutual inductance. In the KPO 101, an oscillation frequency of the KPO 101 or the JPO 1011 can be adjusted by the DC bias current flowing through the pump line. When a current that is a pump wave flows through the inductor 1014, the entirety of the KPO 101 operates as an oscillator due to inductive coupling by the mutual inductance described above. The dc-SQUID operates as an inductor having a variable non-linear inductance in which the inductance changes depending on the magnetic flux passing through the inductor.

As the branch unit 102, a circulator is generally used. In a case where the branch unit 102 is a circulator, the branch unit 102 receives a phase lock signal (which will be described later) that is output from the first adjustment device 40, and of which amplitude is adjusted. The branch unit 102 outputs the received phase lock signal to the KPO 101. The branch unit 102 outputs a reflection signal of the phase lock signal reflected by the KPO 101 to the combiner 103.

The combiner 103 receives a reflection signal output from the branch unit 102 and a cancellation signal (which will be described later) output from the second adjustment device 50. The combiner 103 mixes the received reflection signal and the received cancellation signal. The combiner 103 outputs a mixed signal obtained by mixing the reflection signal and the cancellation signal to the amplifier 104.

The amplifier 104 receives the mixed signal from the combiner 103. The amplifier 104 amplifies an amplitude of the received mixed signal. The amplifier 104 outputs the mixed signal with the amplified amplitude to the pulse measurement device 60.

The DC source 20 outputs a bias current to the KPO 101. The resonance frequency of the KPO 101 or the JPO 1011 can be adjusted by the bias current.

The pulse generation device 30 outputs, to the KPO 101, a signal (current) having a frequency of about twice the resonance frequency adjusted by the bias current. With this signal, the resonators 1011c and 1011d and the dc-SQUID oscillate at an oscillation frequency that is half a pump frequency (about twice the resonance frequency) that is a frequency of a pump wave.

The pulse generation device 30 outputs the phase lock signal to the first adjustment device 40. The pulse generation device 30 outputs a signal obtained by inverting the phase lock signal to the second adjustment device 50. For example, the pulse generation device 30 includes a local oscillator (LO) 301, an arbitrary waveform generator (AWG) 302, radio frequency (RF) mixers 303 and 304, and the like, which will be described later.

Here, generation of a signal output from the pulse generation device 30 will be described. The pulse generation device 30 generates a signal by using the technique described in, for example, YAMAJI and 7 others, “Correlated oscillations in Kerr parametric oscillators with tunable effective coupling”, [online], Jun. 28, 2023, arXiv, [retrieved on Dec. 16, 2024], and the Internet (URL: https://arxiv.org/abs/2010.02621), which is the non-patent literature.

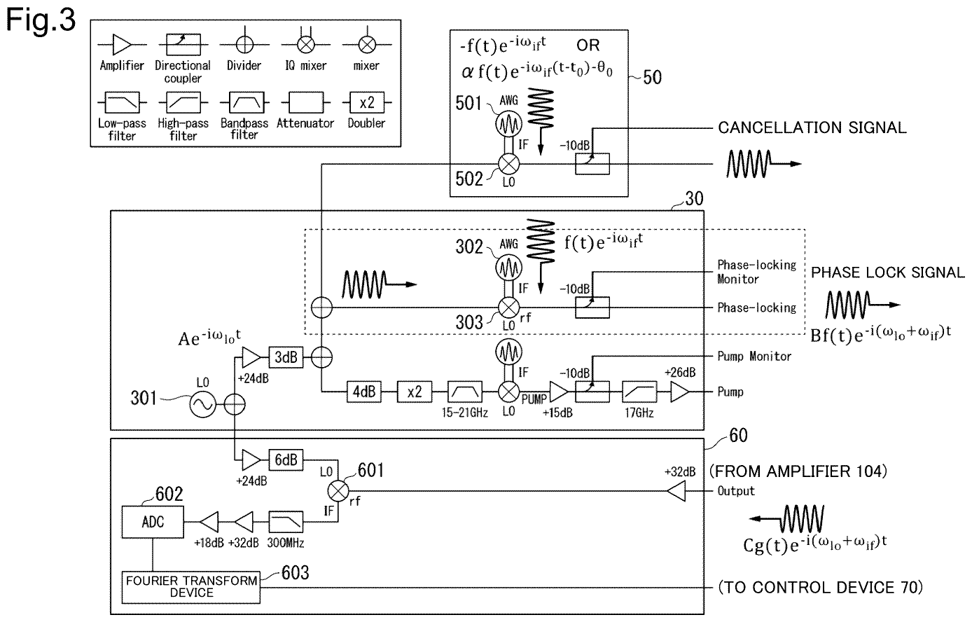

FIG. 3 is a diagram for describing processing performed by the pulse generation device 30 and the pulse measurement device 60 according to some example embodiments of the present disclosure. FIG. 3 is a diagram in which FIG. 8 of the above non-patent literature “Correlated oscillations in Kerr parametric oscillators with tunable effective coupling” having a function of generating a signal is cited, and a new configuration, a specific signal, and the like of the present disclosure are added to FIG. 8. The pulse generation device 30 illustrated in FIG. 3 includes an LO 301, an AWG 302, and an RF mixer 303. The pulse generation device 30 executes processing as follows.

For example, in the pulse generation device 30, the LO 301 generates a signal described in Expression (1). The LO 301 outputs the generated signal described in Expression (1) to the pulse measurement device 60.

$$\begin{matrix}[ Math . 1 ] & \\ {e}^{- i {ω}_{l o} t} & ( 1 )\end{matrix}$$

The signal described in Expression (1) is a signal having an amplitude of A and an angular frequency of ωlo (for example, 10 GHz in frequency conversion). The amplitude A is set to a value at which the RF mixer 303 is saturated. The amplitude A is a fixed value. The AWG 302 generates a signal described in Expression (2).

$$\begin{matrix}[ Math . 2 ] & \\ f ( t ) {e}^{- i {ω}_{if} t} & ( 2 )\end{matrix}$$

The signal described in Expression (2) is a signal having an amplitude of f(t) and an angular frequency of ωif (for example, 10 MHz in frequency conversion). The RF mixer 303 multiplies a continuous wave having an angular frequency of ωlo output from the LO 301 and an intermediate frequency (IF) pulse wave having an angular frequency of ωif output from the AWG 302. As a result, the RF mixer 303 generates a signal described in Expression (3). The RF mixer 303 outputs the generated signal to the first adjustment device 40.

$$\begin{matrix}[ Math . 3 ] & \\ B f ( t ) {e}^{- i ( {ω}_{l o} + {ω}_{if} ) t} & ( 3 )\end{matrix}$$

As described above, the amplitude A is set to a value at which the RF mixer 303 is saturated, and is a fixed value. Therefore, the signal described in Expression (3) is a trapezoidal wave micropulse such as a signal in which a cosine function is convoluted into a trapezoid. An amplitude B can be changed by changing the amplitude A. However, since the RF mixer 303 is saturated, the amplitude of Expression (3) can be adjusted with higher accuracy by adjusting f(t).

The first adjustment device 40 adjusts the amplitude of the phase lock signal output from the pulse generation device 30. The first adjustment device 40 outputs the phase lock signal whose amplitude has been adjusted to the branch unit 102. For example, the first adjustment device 40 has a function of attenuating the amplitude, such as variable shielding.

The second adjustment device 50 adjusts an amplitude or a phase of a signal obtained by inverting the phase lock signal output from the pulse generation device 30. For example, as illustrated in FIG. 3, the second adjustment device 50 includes an AWG 501 and an RF mixer 502. The AWG 501 generates a signal described in Expression (4) as an initial signal output from the AWG 501. The second adjustment device 50 outputs a signal whose amplitude or phase has been adjusted, to the combiner 103 as the cancellation signal.

For example, the second adjustment device 50 has a function of attenuating the amplitude, such as variable shielding. For example, the second adjustment device 50 has a function of adjusting a phase, such as a phase shifter.

$$\begin{matrix}[ Math . 4 ] & \\ - f ( t ) {e}^{- i {ω}_{if} t} & ( 4 )\end{matrix}$$

The pulse measurement device 60 measures the mixed signal output from the amplifier 104. For example, the pulse measurement device 60 measures the mixed signal before the first adjustment device 40 or the second adjustment device 50 is controlled by the control device 70 to change parameters to be described later. The control of the first adjustment device 40 or the second adjustment device 50 by the control device 70 is control for changing a parameter to be described later. The pulse measurement device 60 stores a measurement result. The pulse measurement device 60 measures the mixed signal every time the first adjustment device 40 or the second adjustment device 50 is controlled. The pulse measurement device 60 stores the measurement result.

Specifically, the pulse measurement device 60 illustrated in FIG. 3 includes an RF mixer 601, an analog to digital converter (ADC) 602, and a Fourier transform device 603. The pulse measurement device 60 executes processing as follows.

For example, in the pulse generation device 30 illustrated in FIG. 3, the LO 301 generates the signal described in Expression (1). In the pulse measurement device 60, the RF mixer 601 receives a signal described in Expression (5) from the dilution refrigerator 10.

$$\begin{matrix}[ Math . 5 ] & \\ Cg ( t ) {e}^{- i ( {ω}_{l o} + {ω}_{if} ) t} & ( 5 )\end{matrix}$$

The signal described in Expression (5) is an output pulse wave of a quantum bit by the KPO 101 or the JPO 1011, and is a micropulse of a trapezoidal wave such as a signal in which a cosine function is convolved into a trapezoid. Specifically, the signal described in Expression (5) is a signal output from the amplifier 104 to the pulse measurement device 60. The RF mixer 601 multiplies the micropulse of a trapezoidal wave output from the amplifier 104 and a continuous wave that is output from the LO 301 and has an angular frequency of @lo. As a result, the RF mixer 601 generates a signal described in Expression (6). The signal described in Expression (6) is an IF pulse wave having an angular frequency of ωif. The RF mixer 601 outputs the generated IF pulse wave to the ADC 602.

$$\begin{matrix}[ Math . 6 ] & \\ Dg ( t ) {e}^{- i {ω}_{if} t} & ( 6 )\end{matrix}$$

The ADC 602 receives the IF pulse wave from the RF mixer 601. The ADC 602 measures the received IF pulse wave. Specifically, the ADC 602 converts the received IF pulse wave from an analog signal to a digital signal. The ADC 602 outputs the IF pulse wave after conversion, to the Fourier transform device 603.

The Fourier transform device 603 receives the IF pulse wave from the ADC 602. The Fourier transform device 603 performs Fourier transform on the received IF pulse wave at a frequency relevant to the angular frequency ωif. As a result, the Fourier transform device 603 can acquire the amplitude and the phase at a fundamental frequency of the IF pulse wave. Specifically, the Fourier transform device 603 obtains a complex amplitude of an IQ signal by multiplying the IF pulse wave by the cos wave/sin wave. The Fourier transform device 603 outputs a result of the Fourier transform to the control device 70.

The control device 70 receives the Fourier transform result from the Fourier transform device 603. Every time the control device 70 controls the first adjustment device 40 or the second adjustment device 50 (that is, every time the control device 70 receives a new Fourier transform result), the control device 70 controls the first adjustment device 40 or the second adjustment device 50 based on the received result of the Fourier transform. Specifically, as described above, the first adjustment device 40 adjusts the amplitude of the phase lock signal output from the pulse generation device 30. Alternatively, as described above, the second adjustment device 50 adjusts the amplitude or the phase of the signal obtained by inverting the phase lock signal output from the pulse generation device 30. That is, in a case where the signal described in Expression (2) is used as a reference, the cancellation signal can be described as described in Expression (7).

$$\begin{matrix}[ Math . 7 ] & \\ α f ( t ) {e}^{- i {ω}_{if} ( t - {t}_{0} ) - {θ}_{0}} & ( 7 )\end{matrix}$$

α in Expression (7) is an amplitude ratio in a case where the signal described in Expression (2) is used as a reference. θ0 in Expression (7) is an initial phase in a case where the signal described in Expression (2) is used as the reference.

t0 in Expression (7) is a time delay in a case where the signal described in Expression (2) is used as the reference.

Therefore, when the control device 70 controls the first adjustment device 40 or the second adjustment device 50, the amplitude ratio α, the initial phase θ0, or the time delay t0 in Expression (7) is adjusted. Each of the amplitude ratio α, the initial phase θ0, and the time delay t0 is an example of a parameter.

Specifically, the control device 70 makes the cancellation pulse waveform wider than a signal wave that is the signal described in Expression (2). The control device 70 adjusts the amplitude ratio α and the initial phase θ0 by controlling the first adjustment device 40 or the second adjustment device 50. The ADC 602 measures the received IF pulse wave every time the IF pulse wave is received from the RF mixer 601. The ADC 602 outputs the IF pulse wave after conversion, to the Fourier transform device 603. The Fourier transform device 603 receives the IF pulse wave from the ADC 602. The Fourier transform device 603 performs Fourier transform on the received IF pulse wave at a frequency relevant to the angular frequency ωif. Then, the Fourier transform device 603 outputs a result of the Fourier transform to the control device 70. Therefore, the control device 70 controls the first adjustment device 40 or the second adjustment device 50 based on the received result of the Fourier transform every time the first adjustment device 40 or the second adjustment device 50 is controlled (that is, every time a new Fourier transform result is received). By repeating these processes, the control device 70 obtains the amplitude ratio α and the initial phase θ0 at which the amplitude of the IF pulse wave is minimized within a range in which repetition is performed. For example, when the amplitude ratio α or the initial phase θ0 that is the parameter swings (when the amplitude ratio α or the initial phase θ0 is changed by a minute value), these processes may be repeated by performing a sequence of fitting the amplitude of the IF pulse wave measured by swinging the parameter by three points to a quadratic function and moving the IF pulse wave to a parameter at which the amplitude of the IF pulse is minimized while reducing the swing width of the parameter.

Unless the cancellation pulse waveform temporally overlaps with the signal wave that is the signal described in Expression (2), it is not possible to adjust the amplitude and the phase of the cancellation pulse waveform. Therefore, at an initial stage of calibration, it is desirable to set and adjust the input of the cancellation pulse waveform to be longer in terms of time. That is, “making the cancellation pulse waveform wider than the signal wave that is the signal described in Expression (2)” means that it is desirable to set and adjust the input of the cancellation pulse waveform to be longer in terms of time at the initial stage of calibration.

As the calibration progresses, the length of the cancellation pulse waveform may be brought back to the same length as the signal wave that is the signal described in Expression (2).

For the adjustment of the time delay t0 as a parameter, for example, the time delay t0 in which the amplitude of the IF pulse wave is minimized by sweeping the time delay t0 may be obtained by adjusting an output timing of the IF pulse wave by the AWG 302.

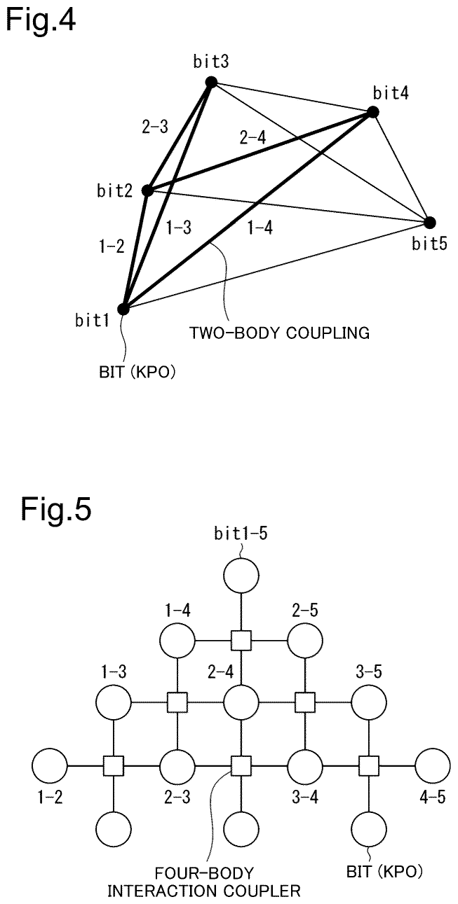

In the processing system 1 illustrated in FIG. 1, only one KPO 101 is illustrated. In practice, however, the processing system 1 includes a plurality of KPOs 101 and a capacitor 80 for each of the plurality of KPOs 101 to couple with the adjacent KPO 101. FIG. 4 is a first diagram illustrating an image of a configuration of the processing system 1 including the capacitor 80 according to some example embodiments of the present disclosure. FIG. 5 is a second diagram illustrating an image of a configuration of the processing system 1 including the capacitor 80 according to some example embodiments of the present disclosure. FIG. 4 is a diagram illustrating an image of the configuration of the processing system 1 by a graph of full coupling of two-body coupling. FIG. 5 is a diagram illustrating an image of the configuration of the processing system 1 by a graph of a Lechner-Hauke-Zoller (LHZ) method using four-body coupling. In FIGS. 4 and 5, each circle representing a bit is one KPO 101. In FIGS. 4 and 5, the capacitor 80 is provided on a wiring connecting the circles (that is, KPOs 101).

The processing system 1 has a configuration to generate the above-described respective signals described with reference to FIGS. 1 to 3 for the plurality of KPOs 101, input the signals to the KPOs 101, and adjust the signals.

The above-described processing performed by the processing system 1 according to one example embodiment of the present disclosure is an example, and is not limited to the above-described processing. For example, the processing system 1 may execute processing described below.

(Processing performed by Processing System in Present Disclosure)

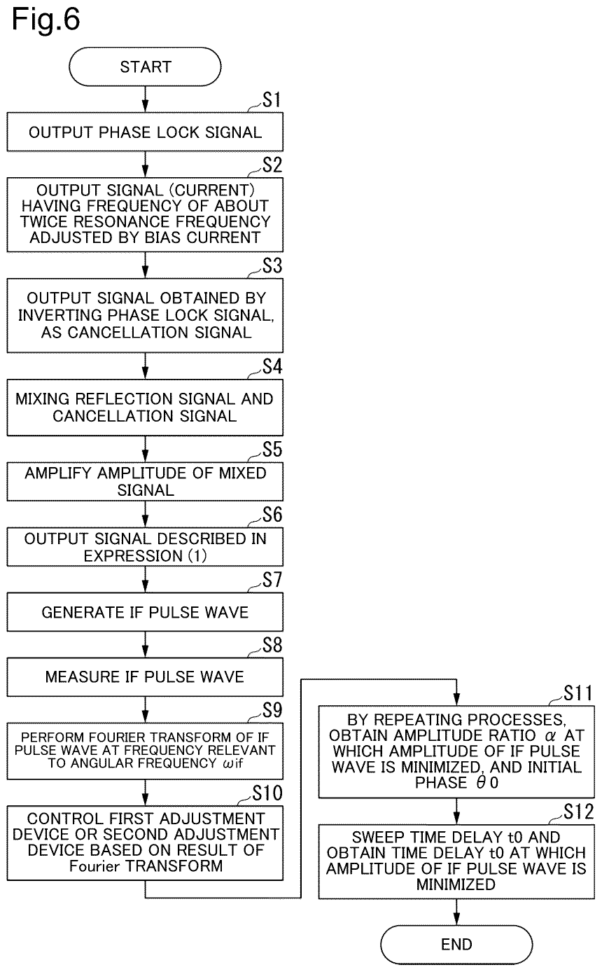

FIG. 6 is a diagram illustrating an example of a processing flow of the processing system 1 according to some example embodiments of the present disclosure. Here, processing of determining the above-described parameters performed by the processing system 1 illustrated in FIG. 6 will be described. Here, the processing of determining the above-described parameters for one KPO 101 will be described, but in the processing system 1, similar processing is performed for each of the plurality of KPOs 101.

The pulse generation device 30 outputs the phase lock signal to the first adjustment device 40 (Step S1). The first adjustment device 40 outputs the phase lock signal to the dilution refrigerator 10. The pulse generation device 30 outputs, to the KPO 101, a signal (current) having a frequency of about twice the resonance frequency adjusted by the bias current (Step S2). As a result, the KPO 101 oscillates at a half frequency of a signal having a frequency of about twice the resonance frequency. The KPO 101 outputs the reflection signal of the phase lock signal to the combiner 103. The KPO 101 does not need to oscillate at the calibration stage. Therefore, at the calibration stage, only the phase lock signal and the cancellation signal may be applied to the combiner 103.

The pulse generation device 30 outputs a signal obtained by inverting the phase lock signal to the second adjustment device 50 as the cancellation signal (Step S3). The second adjustment device 50 outputs the signal obtained by inverting the phase lock signal to the combiner 103. The combiner 103 receives the reflection signal and the cancellation signal. The combiner 103 mixes the received reflection signal and the received cancellation signal (Step S4). The combiner 103 outputs a mixed signal that is a signal obtained by mixing, to the amplifier 104.

The amplifier 104 receives the mixed signal from the combiner 103. The amplifier 104 amplifies the amplitude of the received mixed signal (Step S5). The amplifier 104 outputs the mixed signal with the amplified amplitude to the pulse measurement device 60. The pulse generation device 30 outputs the signal described in Expression (1) to the pulse measurement device 60 (Step S6).

The RF mixer 601 receives a micropulse of a trapezoidal wave, which is a mixed signal with amplified amplitude, from the amplifier 104. The RF mixer 601 receives a continuous wave that has an angular frequency of ωlo, is output from the LO 301, and is the signal described in Expression (1). The RF mixer 601 multiplies the micropulse of a trapezoidal wave output from the amplifier 104 and a continuous wave that is output from the LO 301 and has an angular frequency of ωlo. As a result, the RF mixer 601 generates an IF pulse wave having an angular frequency of ωif, which is the signal described in Expression (6) (Step S7). The RF mixer 601 outputs the generated IF pulse wave to the ADC 602.

The ADC 602 receives the IF pulse wave from the RF mixer 601. The ADC 602 measures the received IF pulse wave (Step S8). Specifically, the ADC 602 converts the received IF pulse wave from an analog signal to a digital signal. The ADC 602 outputs the IF pulse wave after conversion, to the Fourier transform device 603.

The Fourier transform device 603 receives the IF pulse wave from the ADC 602. The Fourier transform device 603 performs Fourier transform on the received IF pulse wave at a frequency relevant to the angular frequency ωif (Step S9). As a result, the Fourier transform device 603 can acquire the amplitude at a fundamental frequency of the IF pulse wave. The Fourier transform device 603 outputs a result of the Fourier transform to the control device 70.

The control device 70 receives the Fourier transform result from the Fourier transform device 603. Every time the control device 70 controls the first adjustment device 40 or the second adjustment device 50 (that is, every time the control device 70 receives a new Fourier transform result), the control device 70 controls the first adjustment device 40 or the second adjustment device 50 based on the received result of the Fourier transform (Step S10). The control device 70 controls the first adjustment device 40 or the second adjustment device 50 based on the received result of the Fourier transform every time the first adjustment device 40 or the second adjustment device 50 is controlled (that is, every time a new Fourier transform result is received). By repeating these processes, the control device 70 obtains the amplitude ratio α and the initial phase θ0 at which the amplitude of the IF pulse wave is minimized within a range in which repetition is performed (Step S11). The control device 70 adjusts the second adjustment device 50 after making the cancellation pulse waveform equivalent to the signal wave that is the signal described in Expression (2), thereby sweeping the time delay t0 and obtaining the time delay t0 at which the amplitude of the IF pulse wave is minimized (Step S12).

The above-described adjustment of the parameter of the signal performed by the control device 70 may be manual adjustment by a person.

### (Advantages)

The processing system 1 (an example of a processing device) includes: a control device 70 (an example of input means) that inputs a phase lock signal (an example of a first signal wave) for controlling an oscillation state of a KPO 101 (an example of an oscillator) to which a branch unit 102 having an input unit and an output unit is connected, to the KPO 101 via the input unit; a pulse measurement device 60 (an example of reading means) that is connected to the output unit and reads the oscillation state of the KPO 101; and a combiner 103 (an example of mixing means) that mixes a cancellation signal (an example of a second signal wave) that is a wave having an opposite phase to a reflected wave of the first signal wave, with the phase lock signal mixed in the output unit, between the output unit and the pulse measurement device 60. With this processing system 1, it is possible to reduce a reflected wave (that is, an input wave that is reflected by the oscillator and is generated when the oscillator oscillates) of the phase lock signal generated when the oscillator oscillates.

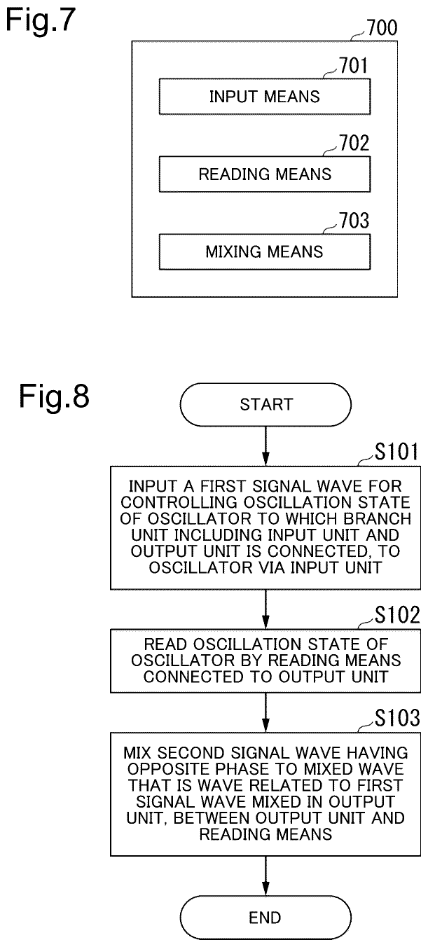

FIG. 7 is a diagram illustrating an example of a configuration of a processing device 700 according to some example embodiments of the present disclosure. As illustrated in FIG. 7, the processing device 700 includes input means 701, reading means 702, and mixing means 703.

The input means 701 inputs a first signal wave for controlling an oscillation state of an oscillator to which a branch unit including an input unit and an output unit is connected, to the oscillator via the input unit. The reading means 702 is connected to the output unit and reads the oscillation state of the oscillator. The mixing means 703 mixes the first signal wave mixed in the output unit with a second signal wave that is a wave having an opposite phase to a reflected wave of the first signal wave, between the output unit and the reading means.

The processing device 700 can be achieved by using, for example, the functions of the processing system 1 illustrated in FIG. 1. The input means 701 can be achieved by using, for example, the functions of the control device 70 illustrated in FIG. 1. The reading means 702 can be achieved by using, for example, the functions of the pulse measurement device 60 illustrated in FIG. 1. The mixing means 703 can be achieved by using, for example, the functions of the combiner 103 illustrated in FIG. 1.

Next, processing performed by the processing device 700 according to some example embodiments of the present disclosure will be described. FIG. 8 is a diagram illustrating an example of a processing flow of the processing device 700 according to some example embodiments of the present disclosure. Here, the processing of the processing device 700 will be described with reference to FIG. 8.

The input means 701 inputs a first signal wave for controlling an oscillation state of an oscillator to which a branch unit including an input unit and an output unit is connected, to the oscillator via the input unit (Step S101). The mixing means 703 mixes the first signal wave mixed in the output unit with a second signal wave that is a wave having an opposite phase to a reflected wave of the first signal wave, between the output unit and the reading means (Step S102). The reading means 702 is connected to the output unit and reads the oscillation state of the oscillator (Step S103).

The processing device 700 according to some example embodiments of the present disclosure has been described above. With the processing device 700, it is possible to reduce a reflected wave (that is, the input wave reflected by the oscillator) of the phase lock signal generated when the oscillator oscillates.

The order of processing in each example embodiment of the present disclosure may be changed within a range in which appropriate processing is performed.

Although the example embodiments of the present disclosure have been described, the processing system 1, the dilution refrigerator 10, the DC source 20, the pulse generation device 30, the first adjustment device 40, the second adjustment device 50, the pulse measurement device 60, and other control devices, which have been described above, may include a computer system inside. The process of the above-described processing is stored in a computer-readable recording medium in a form of a program, and the above-described processing is executed by the computer reading and executing the program. A specific example of the computer will be described below.

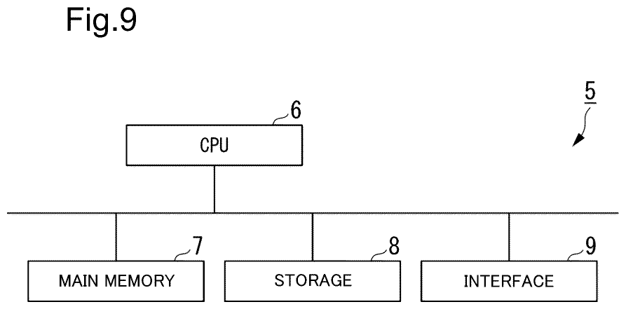

FIG. 9 is a schematic block diagram illustrating a configuration of a computer according to at least one example embodiment. As illustrated in FIG. 9, the computer 5 includes a central processing unit (CPU) 6, a main memory 7, a storage 8, and an interface 9.

For example, each of the processing system 1, the dilution refrigerator 10, the DC source 20, the pulse generation device 30, the first adjustment device 40, the second adjustment device 50, the pulse measurement device 60, and other control devices, which have been described above, is mounted on the computer 5. The operation of each processing unit described above is stored in the storage 8 in the form of the program. The CPU 6 reads the program from the storage 8, loads the program in the main memory 7, and executes the above processing according to the program. The CPU 6 secures a storage area associated with each of the above-described storage units in the main memory 7 according to the program.

Examples of the storage 8 include a hard disk drive (HDD), a solid state drive (SSD), a magnetic disk, a magneto-optical disk, a compact disc read only memory (CD-ROM), a digital versatile disc read only memory (DVD-ROM), a semiconductor memory, and the like. The storage 8 may be an internal medium directly connected to the bus of the computer 5 or an external medium connected to the computer 5 via the interface 9 or a communication line. In a case where the program is distributed to the computer 5 through a communication line, the computer 5 that has received the distribution may develop the program in the main memory 7 and execute the above processing. In at least one example embodiment, the storage 8 is a non-transitory tangible storage medium.

The program may achieve a part of the functions described above. The program may be a file that can achieve the above-described functions in combination with a program already recorded in the computer system, that is, a so-called difference file (difference program).

Although some example embodiments of the present disclosure have been described, these example embodiments are examples and do not limit the scope of the disclosure. Various additions, omissions, substitutions, and changes may be made to these example embodiments without departing from the gist of the disclosure.

Some or all of the above example embodiments may be described as the following Supplementary Notes, but are not limited to the following.

### (Supplementary Note 1)

A processing device including:
input means for inputting a first signal wave for controlling an oscillation state of an oscillator to the oscillator to which a branch unit including an input unit and an output unit is connected, via the input unit;
reading means for reading the oscillation state of the oscillator, which is connected to the output unit; and
mixing means for mixing a second signal wave that is a wave having a phase opposite to a phase of a reflected wave of a first signal wave mixed in the output unit, with the first signal wave between the output unit and the reading means.

### (Supplementary Note 2)

The processing device according to Supplementary Note 1, in which
the branch unit
is a circulator.

### (Supplementary Note 3)

The processing device according to Supplementary Note 1 or 2, in which
the oscillator
is a parametric oscillator and oscillates by a pump wave passing through a path separate from a path of the input unit.

### (Supplementary Note 4)

The processing device according to any one of Supplementary Notes 1 to 3, in which
the first signal wave
is a signal for controlling a phase of the oscillator.

### (Supplementary Note 5)

The processing device according to any one of Supplementary Notes 1 to 4, further including:
an amplifier provided between the output unit and the reading means, in which
the mixing means
mixes the second signal wave between the output unit and the amplifier.

### (Supplementary Note 6)

The processing device according to any one of Supplementary Notes 1 to 5, further including:
a separate oscillator from the oscillator, which is connected to the oscillator via a coupler with passing through a path separate from a path of the input unit.

### (Supplementary Note 7)

The processing device according to any one of Supplementary Notes 1 to 6, in which
the oscillator
constitutes a quantum bit.

### (Supplementary Note 8)

A processing method including:
inputting a first signal wave for controlling an oscillation state of an oscillator to the oscillator to which a branch unit including an input unit and an output unit is connected, via the input unit;
reading the oscillation state of the oscillator by reading means connected to the output unit; and
mixing a second signal wave that is a wave having a phase opposite to a phase of a reflected wave of a first signal wave mixed in the output unit, with the first signal wave between the output unit and the reading means.

### (Supplementary Note 9)

The processing method according to Supplementary Note 8, in which
the branch unit
is a circulator.

### (Supplementary Note 10)

The processing method according to Supplementary Note 8 or 9, in which
the oscillator
is a parametric oscillator and oscillates by a pump wave passing through a path separate from a path of the input unit.

### (Supplementary Note 11)

The processing method according to any one of Supplementary Notes 8 to 10, in which
the first signal wave
is a signal for controlling a phase of the oscillator.

### (Supplementary Note 12)

The processing method according to any one of Supplementary Notes 8 to 11, further including:
mixing the second signal wave between the output unit and an amplifier provided between the output unit and the reading means.

### (Supplementary Note 13)

The processing method according to any one of Supplementary Notes 8 to 12, in which
the processing method is performed by a processing device, and
the processing device includes
a separate oscillator from the oscillator, which is connected to the oscillator via a coupler with passing through a path separate from a path of the input unit.

### (Supplementary Note 14)

The processing method according to any one of Supplementary Notes 8 to 13, in which
the oscillator
configures a quantum bit.

### (Supplementary Note 15)

A program for causing a computer to execute:
inputting a first signal wave for controlling an oscillation state of an oscillator to the oscillator to which a branch unit including an input unit and an output unit is connected, via the input unit;
reading the oscillation state of the oscillator by reading means connected to the output unit; and
mixing a second signal wave that is a wave having a phase opposite to a phase of a reflected wave of a first signal wave mixed in the output unit, with the first signal wave between the output unit and the reading means.

### (Supplementary Note 16)

The program according to Supplementary Note 15, in which
the branch unit
is a circulator.

### (Supplementary Note 17)

The program according to Supplementary Note 15 or 16, in which
the oscillator
is a parametric oscillator and oscillates by a pump wave passing through a path separate from a path of the input unit.

### (Supplementary Note 18)

The program according to any one of Supplementary Notes 15 to 17, in which
the first signal wave
is a signal for controlling a phase of the oscillator.

### (Supplementary Note 19)

The program according to any one of Supplementary Notes 15 to 18, the program for causing the computer to further execute:
mixing the second signal wave between the output unit and an amplifier provided between the output unit and the reading means.

### (Supplementary Note 20)

The program according to any one of Supplementary Notes 15 to 19, in which
the computer is included in a processing device, and
the processing device includes
a separate oscillator from the oscillator, which is connected to the oscillator via a coupler with passing through a path separate from a path of the input unit.

### (Supplementary Note 21)

The program according to any one of Supplementary Notes 15 to 20, in which
the oscillator
configures a quantum bit.

1. A processing device comprising:
an input circuit that inputs a first signal wave for controlling an oscillation state of an oscillator to the oscillator to which a branch unit including an input unit and an output unit is connected, via the input unit;
a reading circuit that reads the oscillation state of the oscillator, which is connected to the output unit; and
a mixer that mixes a second signal wave that is a wave having a phase opposite to a phase of a reflected wave of a first signal wave mixed in the output unit, with the first signal wave between the output unit and the reading circuit.

2. The processing device according to claim 1, wherein
the branch unit
is a circulator.

3. The processing device according to claim 1, wherein
the oscillator
is a parametric oscillator and oscillates by a pump wave passing through a path separate from a path of the input unit.

4. The processing device according to claim 1, wherein
the first signal wave
is a signal for controlling a phase of the oscillator.

5. The processing device according to claim 1, further comprising:
an amplifier provided between the output unit and the reading circuit, wherein
the mixer
mixes the second signal wave between the output unit and the amplifier.

6. The processing device according to claim 1, further comprising:
a separate oscillator from the oscillator, which is connected to the oscillator via a coupler with passing through a path separate from a path of the input unit.

7. The processing device according to claim 1, wherein
the oscillator
constitutes a quantum bit.

8. A processing method comprising:
inputting a first signal wave for controlling an oscillation state of an oscillator to the oscillator to which a branch unit including an input unit and an output unit is connected, via the input unit;
reading the oscillation state of the oscillator by a reading circuit connected to the output unit; and
mixing a second signal wave that is a wave having a phase opposite to a phase of a reflected wave of a first signal wave mixed in the output unit, with the first signal wave between the output unit and the reading circuit.

9. The processing method according to claim 8, wherein
the branch unit
is a circulator.

10. The processing method according to claim 8, wherein
the oscillator
is a parametric oscillator and oscillates by a pump wave passing through a path separate from a path of the input unit.

11. The processing method according to claim 8, wherein
the first signal wave
is a signal for controlling a phase of the oscillator.

12. The processing method according to claim 8, further comprising:
mixing the second signal wave between the output unit and an amplifier provided between the output unit and the reading circuit.

13. The processing method according to claim 8, wherein
the processing method is performed by a processing device, and
the processing device includes
a separate oscillator from the oscillator, which is connected to the oscillator via a coupler with passing through a path separate from a path of the input unit.

14. The processing method according to claim 8, wherein
the oscillator
configures a quantum bit.

15. A tangible and non-transitory storage medium storing a program for causing a computer to execute:
inputting a first signal wave for controlling an oscillation state of an oscillator to the oscillator to which a branch unit including an input unit and an output unit is connected, via the input unit;
reading the oscillation state of the oscillator by a reading circuit connected to the output unit; and
mixing a second signal wave that is a wave having a phase opposite to a phase of a reflected wave of a first signal wave mixed in the output unit, with the first signal wave between the output unit and the reading circuit.
